(19) United States
(12) Patent Application Publication
(10) Pub. No.: US 2025/0118591 A1
(43) Pub. Date: Apr. 10, 2025

(54) METHOD OF PROCESSING SUBSTRATE, METHOD OF MANUFACTURING SEMICONDUCTOR DEVICE, RECORDING MEDIUM, SUBSTRATE TRANSFER APPARATUS, AND SUBSTRATE PROCESSING APPARATUS

(71) Applicant: Kokusai Electric Corporation, Tokyo (JP)

(72) Inventor: Naofumi OHASHI, Toyama-shi (JP)

(73) Assignee: Kokusai Electric Corporation, Tokyo (JP)

(21) Appl. No.: 18/893,519

(22) Filed: Sep. 23, 2024

(30) Foreign Application Priority Data
Oct. 5, 2023 (JP) 2023-173672

(51) Int. Cl. H01L 21/687; B25J 15/00

(52) U.S. Cl. CPC H01L 21/68707; B25J 15/0028

(57) ABSTRACT

There is provided a technique that includes: by using a substrate transfer apparatus including a mounting stage on which a substrate is placed and a gripper capable of gripping the substrate placed on the mounting stage between a first portion and a second portion, moving the substrate placed on the mounting stage toward the first portion by using the second portion that pushes the substrate with a first external force; and gripping the substrate placed on the mounting stage with a second external force or a third external force by using the first portion and the second portion.

### CROSS-REFERENCE TO RELATED APPLICATION

This application is based upon and claims the benefit of priority from Japanese Patent Application No. 2023-173672, filed on Oct. 5, 2023, the entire contents of which are incorporated herein by reference.

### TECHNICAL FIELD

The present disclosure relates to a method of processing a substrate, a method of manufacturing a semiconductor device, a recording medium, a substrate transfer apparatus, and a substrate processing apparatus.

### BACKGROUND

As one step in a manufacturing process of semiconductor devices, a plurality of processings may be performed on substrates within a plurality of process furnaces.

In such an apparatus described above, particles may be generated when transferring a substrate to a process furnace by using a substrate transfer apparatus.

### SUMMARY

The present disclosure provides a technique capable of preventing generation of particles when transferring a substrate by using a substrate transfer apparatus.

According to embodiments of the present disclosure, there is provided a technique that includes: by using a substrate transfer apparatus including a mounting stage on which a substrate is placed and a gripper capable of gripping the substrate placed on the mounting stage between a first portion and a second portion, moving the substrate placed on the mounting stage toward the first portion by using the second portion that pushes the substrate with a first external force; and gripping the substrate placed on the mounting stage with a second external force or a third external force by using the first portion and the second portion.

### BRIEF DESCRIPTION OF DRAWINGS

The accompanying drawings, which are incorporated in and constitute a part of the specification, illustrate embodiments of the present disclosure.

FIG. 1 is an explanatory diagram illustrating a schematic configuration example of a substrate processing apparatus according to embodiments of the present disclosure.

FIG. 2 is a perspective view illustrating an example of a substrate transfer apparatus according to the embodiments of the present disclosure.

FIG. 3A is a plan view of a substrate mounting plate, and FIG. 3B is a side view of the substrate mounting plate.

FIG. 4 is a block diagram illustrating a configuration of a controller in the substrate processing apparatus according to the embodiments of the present disclosure.

FIGS. 5A to 5C are diagrams illustrating an operation of the substrate mounting plate according to embodiments of the present disclosure.

### DETAILED DESCRIPTION

Reference are now made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### (1) Configuration of Substrate Processing Apparatus

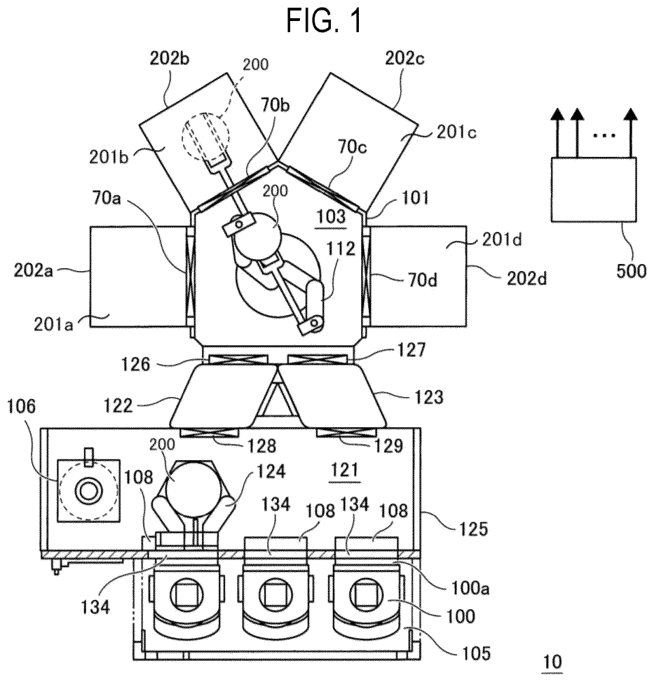

Hereinafter, embodiments of the present disclosure are described mainly with reference to FIGS. 1 to 5C. In addition, the drawings used in the following description are schematic, and dimensional relationships between respective components and proportions of respective components illustrated in the drawings may not correspond to those in reality. Further, the dimensional relationships between respective elements and the proportions of respective elements may not match among multiple drawings.

FIG. 1 is a top cross-sectional view of a substrate processing apparatus 10 for carrying out a method of manufacturing a semiconductor device. The substrate processing apparatus 10 is a cluster type apparatus, and a transfer apparatus is divided into a vacuum side and an atmospheric side. Further, in the substrate processing apparatus 10, a Front Opening Unified Pod (FOUP) (hereinafter referred to as “pod”) 100 is used as a carrier for transferring a wafer 200 serving as a substrate.

### (Configuration of Vacuum Side)

As illustrated in FIG. 1, the substrate processing apparatus 10 includes a first transfer chamber 103 capable of withstanding pressures (negative pressures) lower than atmospheric pressure such as a vacuum state. A housing 101 of the first transfer chamber 103 is, for example, pentagonal in a plane view, and is formed in a box shape with both upper and lower ends closed.

A first substrate transfer apparatus 112 configured to transfer the wafer 200 is installed within the first transfer chamber 103.

A load lock chamber 122 and a load lock chamber 123 are connected, respectively, to a sidewall located on a front side (lower side in FIG. 1) among five sidewalls of the housing 101, via gate valves 126 and 127. These load lock chambers 122 and 123 are configured to be capable of simultaneously handling the function of loading the wafer 200, the function of holding on for the wafer 200, and the function of unloading the wafer 200, and each possesses a structure capable of withstanding negative pressures.

Process containers 202a to 202d, each for performing a desired processing on the wafer 200, are connected adjacently to four sidewalls located on a rear side (back side, in other words, upper side in FIG. 1) among the five sidewalls of the housing 101 of the first transfer chamber 103, respectively via gate valves 70a to 70d.

### (Configuration of Atmospheric Side)

A second transfer chamber 121 capable of transferring the wafer 200 under atmospheric pressure is connected to front sides of the load lock chambers 122 and 123 via gate valves 128 and 129. A second substrate transfer apparatus 124 configured to transfer the wafer 200 is installed in the second transfer chamber 121.

A notch aligner 106 is installed on a left side of the second transfer chamber 121. In addition, the notch aligner 106 may be an orientation flat aligner.

A pod opener 108 and a substrate loading/unloading port 134 for loading or unloading the wafer 200 into or out of the second transfer chamber 121 are installed on a front side of a housing 125 of the second transfer chamber 121. A load port (IO stage) 105 is installed on an opposite side of the pod opener 108 with the substrate loading/unloading port 134 interposed therebetween, i.e., outside the housing 125. The pod opener 108 includes a closure capable of opening or closing a cap 100a of the pod 100 in addition to closing the substrate loading/unloading port 134. Opening or closing the cap 100a of the pod 100 placed on the load port 105 enables entrance or exit of the wafer 200 into or from the pod 100. Further, the pod 100 is supplied to or discharged from the load port 105 by an in-process transfer apparatus (such as OHT) (not illustrated).

### (Configuration of Process Container)

The process containers 202a to 202d include process chambers 201a to 201d, respectively. The process chambers 201a to 201d are configured to communicate with each other in a reduced pressure state through the gate valves 70a to 70d and the first transfer chamber 103. A preset processing is performed on the loaded wafer 200 within each of the process chambers 201a to 201d.

The process containers 202a to 202d include, for example, both single-wafer type and batch type process containers. The process chamber installed within the single-wafer type process container enables a single-wafer processing to be performed on one or several wafers 200 at a time. The process chamber installed within the batch type process container enables a batch processing to be performed on a plurality of wafers 200 at a time.

In each process container, a gas supply system and a gas exhaust system connected to the process container are controlled to supply gases onto the wafer 200 within the process container, thereby performing a predetermined processing. For example, in a state where the wafer 200 is in the single-wafer type process container, a monosilane (SiH₄) gas serving as a silicon-containing gas and an oxygen (O₂) gas serving as an oxygen-containing gas are supplied to the process container to form a silicon oxide film on the wafer 200. Further, in another single-wafer type process container, a SiH₄ gas and a nitrogen (N₂) gas serving as a nitrogen-containing gas are supplied to form a silicon nitride film on the wafer 200. Furthermore, in a state where the wafer 200 is in the batch type process container, annealing is performed to heat the wafer 200 while supplying an inert gas into the process container. In this way, the wafer 200 may be processed differently for each process container. Herein, film formation and annealing are described as examples, but the present disclosure is not limited thereto, and desired substrate processing such as modification or cooling may also be performed in each process container.

### (Configuration of Load Lock Chamber)

Next, the load lock chambers 122 and 123 are described. The load lock chambers 122 and 123 are installed in adjacent to one side, i.e., vacuum side, of the first transfer chamber 103, respectively via the gate valves 126 and 127. Further, the load lock chambers 122 and 123 are installed in adjacent to one side, i.e., atmospheric side of the second transfer chamber 121, respectively via gate valves 128 and 129. The load lock chambers 122 and 123 are configured to communicate with the process chambers 201a to 201d in a reduced pressure state through the gate valves 126 and 127 and the first transfer chamber 103. In other words, the load lock chambers 122 and 123 may communicate with the first transfer chamber 103 in a reduced pressure state through the gate valves 126 and 127. Further, the load lock chambers 122 and 123 are configured to communicate with the second transfer chamber 121 in an atmospheric pressure state through the gate valves 128 and 129.

The load lock chamber 122 stores unprocessed wafers 200 before being transferred to any of the process chambers 201a to 201d. Further, the load lock chamber 123 stores processed wafers 200 that are processed in at least one selected from the group of the process chambers 201a to 201d. In other words, each of the load lock chambers 122 and 123 is a storage chamber for temporarily storing the unprocessed or processed wafers 200.

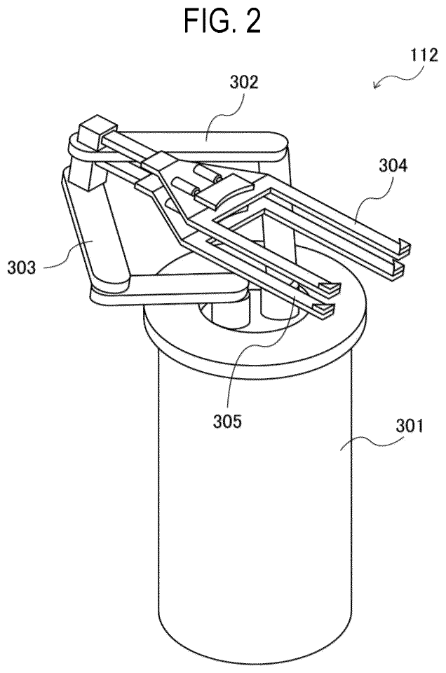

Next, the first substrate transfer apparatus 112 is described in detail with reference to FIG. 2. The first substrate transfer apparatus 112 is configured to be capable of transferring the wafer 200, which is placed on a mounting stage 306 to be described later, to the respective process chambers 201a to 201d. The first substrate transfer apparatus 112 is configured to be moved up and down by an elevator 301. The first substrate transfer apparatus 112 is configured to be capable of transferring two wafers 200 simultaneously by using a scara-type robot.

The first substrate transfer apparatus 112 includes an arm 302 located on an upper side and an arm 303 located on a lower side. End effectors 304 and 305, which serve as substrate mounting plates, are installed, respectively, to tips of the arms 302 and 303. Both the end effectors 304 and 305 are configured to take out and support the wafer 200 from below.

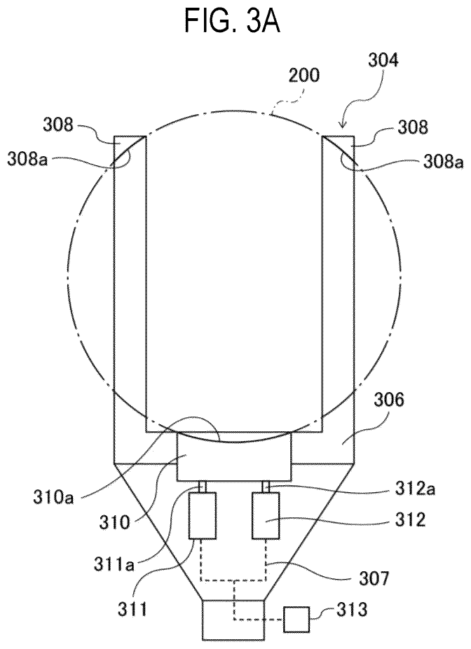

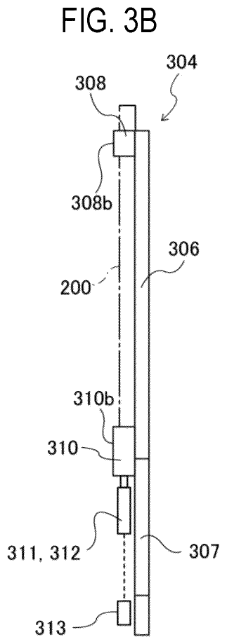

Since the end effectors 304 and 305 are formed to possess substantially the same shape, their configuration is described using the end effector 304 illustrated in FIGS. 3A and 3B as an example.

The end effector 304 includes the mounting stage 306 for placing the wafer 200 thereon, a support 307 for supporting the mounting stage 306, a tip grip 308 provided as a first portion on an upper surface of a tip of the mounting stage 306, and a movable grip 310 provided as a second portion on the upper surface of the mounting stage 306 at a side opposite to the tip grip 308. The movable grip 310 may also be referred to as “rear grip.”

The mounting stage 306 is configured in a U-shaped plate (plate-like body) shape. The mounting stage 306 is not limited to a U-shaped configuration and may also be in a bifurcated fork-like plate shape or a rectangular plate shape, among others. The mounting stage 306 is supported by and fixed to the arm 302 via the support 307.

The tip grip 308 is provided to protrude in a columnar shape from the upper surface of both tips of the mounting stage 306. An inner side surface 308a of the tip grip 308 is formed in an arc shape to match a shape of the wafer 200. A diameter of the inner side surface 308a of the tip grip 308 is set to be slightly larger than a diameter of the wafer 200. Further, an upper surface 308b of the tip grip 308 is configured to be higher than a surface of the wafer 200 placed on the mounting stage 306.

The movable grip 310 is provided to protrude from the upper surface of the mounting stage 306 at a connection portion with the support 307. The movable grip 310 is formed in a rectangular parallelepiped shape, and an inner side surface 310a of the movable grip 310, which faces the tip grip 308, is formed in an arc shape to match the shape of the wafer 200. A diameter of the inner side surface 310a of the movable grip 310 is set to be slightly larger than the diameter of the wafer 200. Further, an upper surface 310b of the movable grip 310 is configured to be higher than the surface of the wafer 200 placed on the mounting stage 306.

Air cylinders 311 and 312 are connected to a side surface of the movable grip 310 opposite to the inner side surface 310a, and serve as movers for moving the movable grip 310 substantially horizontally. The air cylinders 311 and 312 possess substantially the same configuration.

The air cylinders 311 and 312 include rods 311a and 312a, respectively, which are connected at ends thereof to the side surface of the movable grip 310. A pressure regulator 313 is connected to the air cylinders 311 and 312.

The pressure regulator 313 is configured to regulate a pressure of a gas supplied into the air cylinders 311 and 312. This allows for the movement of the movable grip 310, enabling the movable grip 310, along with the tip grip 308, to grip the wafer 200.

Specifically, by regulating the pressure of the gas supplied into the air cylinders 311 and 312 by using the pressure regulator 313, a first external force for pushing the wafer 200 placed on the mounting stage 306 and a second external force for gripping the wafer 200 placed on the mounting stage 306 are regulated. In other words, by regulating the pressure of the gas supplied into the air cylinders 311 and 312, it is configured that the rods 311a and 312a are pushed out of the air cylinders 311 and 312, causing the movable grip 310 to move toward the tip grip 308 by the first external force, and allowing the movable grip 310 and the tip grip 308 to grip the wafer 200 by the second external force.

Further, by regulating the pressure of the gas supplied into the air cylinders 311 and 312 by using the pressure regulator 313, the rods 311a and 312a are retracted into the air cylinders 311 and 312, causing the movable grip 310 to move away from the tip grip 308.

The tip grip 308 and the movable grip 310 are used as a gripper capable of gripping the wafer 200 placed on the mounting stage 306 between the tip grip 308 and the movable grip 310.

### (2) Configuration of Controller

Next, a configuration of a controller 500, which serves as a control part (control means), is described.

The controller 500, serving as the control part (control means), controls each of the above-described components to perform a substrate processing to be described later.

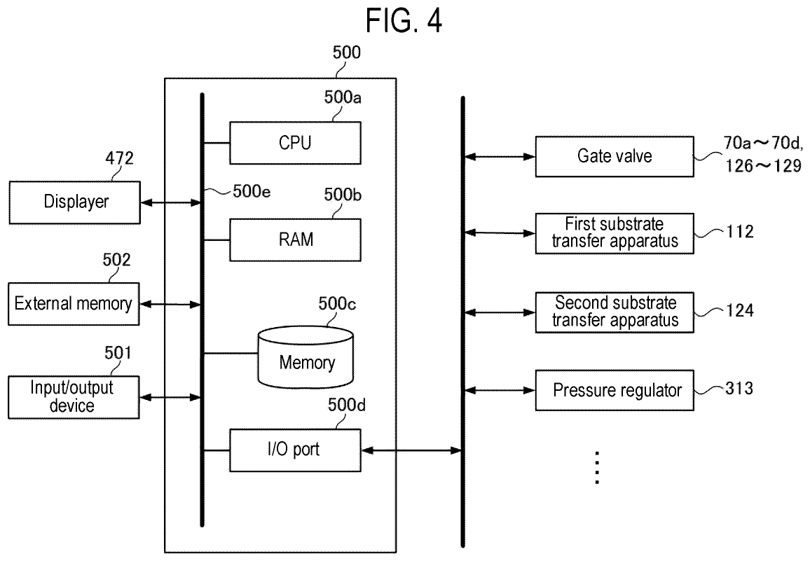

As illustrated in FIG. 4, the controller 500 is configured as a computer including a central processing unit (CPU) 500a, a random access memory (RAM) 500b, a memory 500c, and an I/O port 500d. The RAM 500b, memory 500c, and I/O port 500d are configured to be capable of exchanging data with the CPU 500a through an internal bus 500e. The controller 500 is connected to, for example, an input/output device 501, which is configured as a touch panel and others, and a displayer 472 such as a display.

The memory 500c is composed of, for example, a flash memory, a hard disk drive (HDD), and others. The memory 500c stores, in a readable manner, a control program for controlling the operation of the substrate processing apparatus, a process recipe in which the procedure, condition, and others of a substrate processing to be described later are written, and others. In addition, the process recipe is a combination that causes the controller 500 to execute each procedure of the substrate processing to be described later, achieving predetermined results, and thus functions as a program. Hereinafter, the process recipe, control program, and others are collectively referred to simply as “program.” Further, the term “program” as used herein may refer to a case of solely including the process recipe, a case of solely including the control program, or a case of including both. Further, the RAM 500b is configured as a memory area (work area) where programs, data, and others read by the CPU 500a are temporarily held.

The I/O port 500d is connected to the gate valves 70a to 70d and 126 to 129, first substrate transfer apparatus 112, second substrate transfer apparatus 124, pressure regulator 313, and others.

The CPU 500a is configured to read and execute the control program from the memory 500c. The CPU is also configured to read the process recipe from the memory 500c in response to, e.g., an input of an operation command and the like from the input/output device 501. Then, the CPU 500a is configured to, according to contents of the process recipe thus read, control operations such as the opening and closing of the gate valves 70a to 70d and 126 to 129, the transfer, movement and mounting of the wafer 200 by the first and second substrate transfer apparatuses 112 and 124, and the regulation of the pressure of the gas in the air cylinders by the pressure regulator 313, etc.

In addition, the controller 500 may be configured as a general computer without being limited to be configured as a dedicated computer. For example, the controller 500 according to the present embodiments may be configured by preparing an external memory (e.g., magnetic tapes, magnetic disks such as flexible disks and hard disks, optical disks such as CDs and DVDs, magneto-optical disks such as MOs, and semiconductor memories such as USB memories (USB flash drives) and memory cards) 502 storing the above-described program, and installing a program onto a general computer using the external memory 502. Further, a way for supplying the program to the computer is not limited to supplying it through an external memory 502. For example, the program may be supplied by using a communication means such as the Internet or a dedicated line without the external memory 502. In addition, the memory 500c or the external memory 502 is configured as a computer-readable recording medium. Hereinafter, these are collectively referred to simply as “recording medium.” In addition, when the term “recording medium” is used herein, it may refer to a case of solely including the memory 500c, a case of solely including the external memory 502, or a case of including both.

### (3) Substrate Processing Step

Next, as one step in the semiconductor manufacturing process, a step of processing the wafer 200 by using the substrate processing apparatus 10 with the above-described configuration is described, from the start to the end of the step in the process container 202a. In addition, in the following description, the operation of each component constituting the substrate processing apparatus 10 is controlled by the controller 500.

First, the unprocessed wafer 200 stored in the load lock chamber 122 is loaded into the process chamber 201a of the process container 202a by the first substrate transfer apparatus 112.

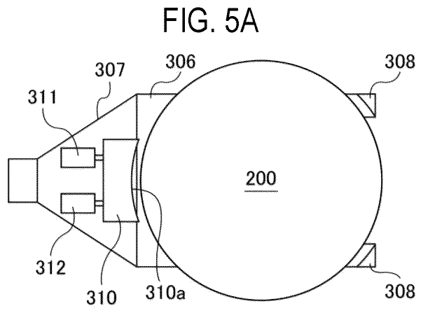

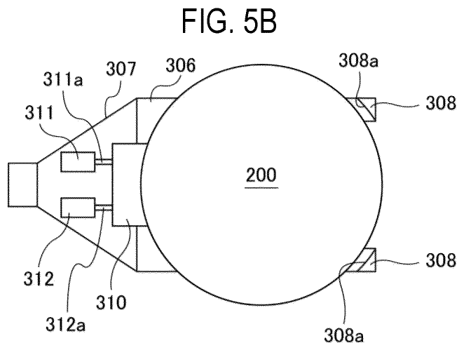

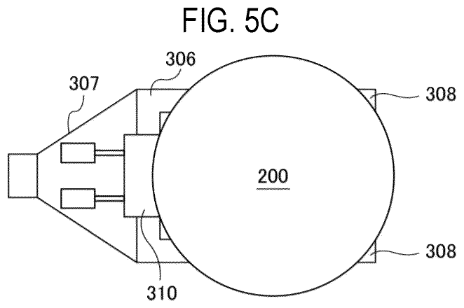

Herein, details of the operation of the first substrate transfer apparatus 112 during the substrate transfer are described in detail with reference to FIGS. 5A to 5C.

First, as illustrated in FIG. 5A, when the wafer 200 is placed on the mounting stage 306 of the first substrate transfer apparatus 112, the controller 500 regulates the pressure of the gas supplied into the air cylinders 311 and 312 to a first pressure by using the pressure regulator 313. The rods 311a and 312a are pushed out of the air cylinders 311 and 312, causing the movable grip 310 to move toward the tip grip 308. Consequently, as illustrated in FIG. 5B, the inner side surface 310a of the movable grip 310 is brought into contact with an end of the wafer 200.

In other words, by regulating the pressure of the gas supplied into the air cylinders 311 and 312 to the first pressure by using the pressure regulator 313, the wafer 200 placed on the mounting stage 306 is moved approximately horizontally as a result of being pushed toward the tip grip 308 with the first external force by the movable grip 310.

Then, after a predetermined time is passed since regulating the pressure of the gas supplied into the air cylinders 311 and 312 to the first pressure, the controller 500 regulates the pressure of the gas supplied into the air cylinders 311 and 312 to a second pressure, which is lower than the first pressure, by using the pressure regulator 313. The rods 311a and 312a are further pushed out of the air cylinders 311 and 312, causing the movable grip 310 and the tip grip 308 to grip the wafer 200. Consequently, as illustrated in FIG. 5C, the end of the wafer 200 is brought into contact with the inner side surface 308a of the tip grip 308, and the wafer 200 is gripped by the tip grip 308 and the movable grip 310.

In other words, by regulating the pressure of the gas supplied into the air cylinders 311 and 312 to the second pressure, which is lower than the first pressure, by using the pressure regulator 313, the wafer 200 placed on the mounting stage 306 is gripped by the inner side surface 308a of the tip grip 308 and the inner side surface 310a of the movable grip 310 with the second external force, which is smaller than the first external force. In other words, the first external force is greater than the second external force.

As described above, the controller 500 is configured to be capable of gripping the wafer 200 by controlling the pressure regulator 313 to apply the first external force and the second external force. In this way, by gripping the wafer 200 in multiple stages (two stages in the present embodiments), specifically by differentiating the magnitude of the external force when pushing the wafer 200 on the mounting stage 306 from the magnitude of the external force when gripping the wafer 200, it is possible to prevent chipping and edge delamination, thereby reducing generation of particles, compared to gripping the wafer 200 in a single stage. Furthermore, by making the second external force, which is applied when gripping the wafer 200, smaller than the first external force, which is applied when pushing the wafer 200 on the mounting stage 306, it is possible to further prevent the chipping and edge delamination of the wafer 200, thereby reducing the generation of particles.

Further, while the arms 302 and 303 are in operation and the wafer 200 is being moved by the arms 302 and 303, the controller 500 regulates the pressure of the gas supplied into the air cylinders 311 and 312 to a third pressure, which is equal to or greater than the first pressure, by using the pressure regulator 313. The rods 311a and 312a are further pushed out of the air cylinders 311 and 312, causing the movable grip 310 and the tip grip 308 to grip the wafer 200 with a third external force, which is equal to or greater than the first external force and also greater than the second external force.

In other words, by regulating the pressure of the gas supplied into the air cylinders 311 and 312 to the third pressure, which is equal to or greater than the first pressure, by using the pressure regulator 313, the wafer 200 placed on the mounting stage 306 is gripped by the inner side surface 308a of the tip grip 308 and the inner side surface 310a of the movable grip 310 with the third external force, which is greater than the second external force.

As described above, the controller 500 controls the tip grip 308 and the movable grip 310 to grip the wafer 200 with the second external force by the tip grip 308 and the movable grip 310 when the arms 302 and 303 are stationary and the mounting stage 306 is stationary (also referred to as when the end effectors 304 and 305 are stationary). On the other hand, the controller 500 controls the tip grip 308 and the movable grip 310 to grip the wafer 200 with the third external force, which is equal to or greater than the first external force and also greater than the second external force, during the operation of the arms 302 and 303 and the movement of the mounting stage 306 (also referred to as when the end effectors 304 and 305 are in motion). In this way, by increasing the gripping force on the wafer 200 during the operation of the arms 302 and 303 compared to the gripping force when the arms 302 and 303 are stationary, it is possible to prevent the wafer 200 from falling during the operation of the arms 302 and 303, while also preventing the chipping and edge delamination of the wafer 200, thereby reducing the generation of particles.

Once the wafer 200 is loaded into the process chamber 201a as described above, the first substrate transfer apparatus 112 is retracted to outside the process container 202a, and the gate valve 70a is closed to seal the process container 202a. Then, a predetermined processing is performed on the wafer 200 in the process chamber 201a. Herein, for example, while the wafer 200 is in the process container 202a, a SiH₄ gas serving as a silicon-containing gas and an O₂ gas serving as an oxygen-containing gas are supplied to the process container 202a to form a silicon oxide film on the wafer 200. In addition, since the operation of each component by the first substrate transfer apparatus to be described later is the same as in this step, a detailed description is omitted below.

Subsequently, the gate valve 70a is opened for the process chamber 201a to communicate with the first transfer chamber 103. Subsequently, the processed wafer 200 is unloaded from the process chamber 201a by the first substrate transfer apparatus 112.

Then, the processed wafer 200 is loaded into the load lock chamber 123 by the first substrate transfer apparatus 112. Then, after closing the gate valve 127, the gate valve 129 is opened for the load lock chamber 123 to communicate with the second transfer chamber 121. Then, the processed wafer 200 is unloaded from the load lock chamber 123 by the second substrate transfer apparatus 124.

### Other Embodiments

Although the embodiments of the present disclosure are specifically described above, the present disclosure is not limited to the above-described embodiments, and various modifications may be made without departing from the gist of the present disclosure.

For example, in the above-described embodiments, a case where the second external force when gripping the wafer 200 is smaller than the first external force when pushing the wafer 200 on the mounting stage 306 is used for description, but the present disclosure is not limited to this. In other words, the second external force when gripping the wafer 200 may be made greater than the first external force when pushing the wafer 200 on the mounting stage 306. Consequently, chipping and edge delamination when pushing the wafer 200 on the mounting stage 306 may be prevented, thereby preventing the generation of particles.

Further, in the above-described embodiments, a case where two air cylinders 311 and 312 are used to move the movable grip 310 is used for description, but the present disclosure is not limited to this. In other words, a single air cylinder or three or more air cylinders may be used. In this modification as well, the same effects as the above-described embodiments are obtained.

Further, in the above-described embodiments, a case where the air cylinder 311 and the air cylinder 312 possess the same configuration is used for description, but the present disclosure is not limited to this. In other words, the air cylinder 311 and the air cylinder 312 may be connected, respectively, to a first pressure regulator that regulates the gas to the first pressure to move the movable grip 310 and a second pressure regulator that regulates the gas to the second pressure to grip the wafer 200 with the movable grip 310 and the tip grip 308. In this case, the controller 500 is configured to be capable of regulating the first external force and the second external force by using the first pressure regulator and the second pressure regulator. In this modification as well, the same effects as the above-described embodiments are obtained.

Further, in the above-described embodiments, a case where the operation of the first substrate transfer apparatus 112 during the substrate transfer is performed with a passage of time is used for description, but the present disclosure is not limited to this. In other words, it is also possible to perform the operation based on an amount of movement of the wafer 200. In this modification as well, the same effects as the above-described embodiments are obtained.

Further, in the above-described embodiments, a case of transferring and processing the wafer 200 in the process container 202a is used for description, but the present disclosure is not limited to this.

For example, an example in which each of the process containers 202a to 202d allows for different types of processing and in which the wafer 200 is transferred between the process containers by using the first substrate transfer apparatus 112 is described, but the present disclosure is not limited to this, and the first substrate transfer apparatus 112 may be used for transfer between the process containers.

In this modification as well, the same effects as the above-described embodiments are obtained.

Further, it is desirable to prepare recipes used for each processing individually based on the processing contents and to store them in the memory 500c via an electrical communication line or the external memory 502. Then, when initiating each processing, it is desirable for the CPU 500a to select an appropriate recipe from among the multiple recipes stored in the memory 500c based on the processing contents. This allows for formation of various film types, composition ratios, film qualities, and film thicknesses on a single substrate processing apparatus, with enhanced reproducibility. Further, it reduces the burden on operators, minimizing risks of operational errors and enabling a quick initiation of each processing.

Further, the above-described recipes are not limited to newly-created ones but may be prepared by modifying existing recipes already installed in the substrate processing apparatus, for example. When modifying the recipes, the modified recipes may be installed in the substrate processing apparatus via an electrical communication line or a recording medium storing the recipes. Further, the existing recipes already installed in the substrate processing apparatus may be directly modified by operating the input/output device 501 of the existing substrate processing apparatus.

Further, in the above-described embodiments, it is described that the process chambers 201a to 201d include both single-wafer type process chambers and batch type process chambers, but the present disclosure is limited to this. That is, the process chambers may not need to be a mix of the single-wafer type process chambers and batch type process chambers. They may be composed of solely single-wafer type process chambers or solely batch type process chambers. Further, a substrate processing apparatus with a hot-wall type process furnace, a substrate processing apparatus with a cold-wall type process furnace, or other substrate processing apparatuses may be used as the process containers 202a to 202d.

Even when using such a substrate processing apparatus, it is possible to perform each processing using the same processing procedures and processing conditions as in the above-described embodiments, and to achieve the same effects as the above-described embodiments.

Further, the above-described embodiments and modifications may be used in combination as appropriate. The processing procedures and processing condition at this time may be the same as the processing procedures and processing conditions in the above-described embodiments and modifications, for example.

According to the present disclosure in some embodiments, it is possible to prevent generation of particles when transferring a substrate by using a substrate transfer apparatus.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, by using a substrate transfer apparatus including a mounting stage on which the substrate is placed and a gripper capable of gripping the substrate placed on the mounting stage between a first portion and a second portion, the method comprising:
moving the substrate placed on the mounting stage toward the first portion by using the second portion that pushes the substrate with a first external force; and
gripping the substrate placed on the mounting stage with a second external force or a third external force by using the first portion and the second portion.

2. The method of claim 1, wherein the first external force is greater than the second external force.

3. The method of claim 1, wherein the third external force is equal to or greater than the first external force.

4. The method of claim 1, wherein the third external force is greater than the second external force.

5. The method of claim 1, wherein the first portion is a tip grip and the second portion is a movable grip.

6. The method of claim 1, wherein the first portion is provided to protrude from a tip of the mounting stage, and
wherein the second portion is provided on the mounting stage at a side opposite to the first portion.

7. The method of claim 5, wherein a pressure regulator is connected to the movable grip.

8. The method of claim 7, wherein a mover is connected to the pressure regulator, and the mover is an air cylinder, and
wherein the pressure regulator regulates an internal pressure of the air cylinder, causing movement of the movable grip.

9. The method of claim 8, wherein the mover includes a plurality of movers, and
wherein the pressure regulator is connected to each of the plurality of movers.

10. The method of claim 1, wherein the substrate is gripped with the second external force by the first portion and the second portion when the mounting stage is stationary, and
wherein the substrate is gripped with the third external force that is equal to or greater than the first external force by the first portion and the second portion when the mounting stage is moving.

11. The method of claim 1, wherein the substrate is gripped with the second external force by the first portion and the second portion when an arm including the mounting stage is stationary, and
wherein the substrate is gripped with the third external force that is equal to or greater than the first external force by the first portion and the second portion when the arm is moving.

12. The method of claim 1, wherein at least one selected from the group of the first external force, the second external force, and the third external force is regulated by using a pressure regulator that is configured to regulate a pressure of a gas to cause movement of the second portion.

13. The method of claim 1, wherein the first external force and the second external force are regulated by using a first pressure regulator that is configured to regulate a gas to a first pressure to cause movement of the second portion and a second pressure regulator that is configured to regulate a gas to a second pressure to cause the first portion and the second portion to grip the substrate.

14. The method of claim 1, comprising:
processing the substrate in a process chamber.

15. The method of claim 14, wherein the substrate is gripped with the third external force when loading or unloading the substrate into or from the process chamber.

16. A method of manufacturing a semiconductor device, comprising the method of claim 14.

17. A non-transitory computer-readable recording medium recording a program that causes, by a computer, a substrate processing apparatus to perform the method of claim 14.

18. A substrate transfer apparatus that causes the method of claim 1 to be performed.

19. A substrate processing apparatus that performs the method of claim 14.
